(19) United States
(12) Patent Application Publication
(10) Pub. No.: US 2010/0273330 A1
(43) Pub. Date: Oct. 28, 2010

(54) RINSE FORMULATION FOR USE IN THE MANUFACTURE OF AN INTEGRATED CIRCUIT

(75) Inventors: Janos Farkas, Saint Ismier (FR); Maria-Luisa Calvo-Munez, Grenoble (FR); Philippe Monnoyer, Grenoble (FR); Sebastien Petitdidier, Gieres (FR)

Correspondence Address: LARSON NEWMAN & ABEL, LLP, 5914 WEST COURTYARD DRIVE, SUITE 200, AUSTIN, TX, 78730, US

(73) Assignee: CITIBANK N.A. AS COLLATERAL AGENT, NEW YORK (NY)

(21) Appl. No.: 12/377,810

(22) PCT Filed: Aug. 23, 2006
(86) PCT No.: PCT/IB06/03051

§ 371 Date: Feb. 17, 2009

(51) Int. Cl. H01L 21/302; C11D 7/32; H01L 21/461

(52) U.S. Cl. 438/692; 510/175; 257/E21.214; 257/E21.483

(57) ABSTRACT

The present invention relates to a solution for treating a surface of a substrate for use in a semiconductor device. More particularly, the present invention relates to a liquid rinse formulation for use in semiconductor processing, wherein the liquid formulation contains: i. a surface passivation agent; and ii. an oxygen scavenger, wherein the pH of the rinse formulation is 8.0 or greater.

### FIELD OF THE INVENTION

The present invention relates to a solution for treating a surface of a substrate for use in a semiconductor device. More particularly, the present invention relates to a solution containing a surface passivation agent and an oxygen scavenger.

### BACKGROUND TO THE INVENTION

Integrated circuits can be described as interconnected networks of electrical components formed on an insulating (dielectric) surface. Traditionally, the material used to form the interconnects, which take their name from their role in interconnecting the electrical components on the surface, was aluminium. However, recently copper has become the favoured material for the manufacture of interconnects. This is primarily because, as the dimensions of integrated circuits shrink, the resistance of each interconnect and the heat produced by that resistance when the interconnect is in use in the integrated circuit become increasingly significant. In addition, the performance of aluminium interconnects at small length scales decreases in use as a result of the electromigration of the metal into the surrounding materials. Copper interconnects are not subject to the same extent of electromigration. Therefore copper is favoured as an interconnect material because it has a lower resistance and better electro migration performance than aluminium.

However, copper interconnects are usually manufactured by a different process compared to aluminium interconnects. Aluminium interconnects are manufactured by a subtractive process in which a blanket layer of aluminium is deposited onto a surface and is then etched to produce the desired interconnect structure. In contrast, copper interconnects are usually manufactured by a ‘damascene’ or ‘dual damascene’ process, such as that illustrated in FIG. 1. This process typically involves the formation of trenches and/or vias in a surface. A diffusion barrier layer may then be deposited, comprising, for example, tantalum. One of the roles of the diffusion barrier layer is to minimize diffusion of the copper from the interconnects into the dielectric layer when the interconnect is in use in the integrated circuit. A thin copper seed layer may then be deposited into the trenches and/or vias. This is followed by the electro-deposition of the bulk copper interconnect structure. However, the copper interconnect resulting from the deposition of the copper is not uniformly contained in the trenches and/or vias, and copper often overflows from the inlaid trench structure onto the surface. Therefore the surface is polished to regain the self-contained inlaid structure. This polishing process is generally carried out by Chemical Mechanical Polishing (CMP). It may be carried out in two stages. The first stage removes the excess copper deposited by the electro-deposition from the surface of the substrate. The second stage removes any of the diffusion barrier material (for example, tantalum) remaining on the dielectric surface between the copper lines, while at the same time making sure that the surface is flat. After CMP, a thin capping layer is usually also deposited on top of the interconnect to prevent copper diffusion into surrounding materials. Examples of materials for the capping layer include silicon nitride-containing films (for conformal deposition) and cobalt or nickel-containing films (for selective deposition).

It is often beneficial to treat the surface of the substrate with a solution before and after each manufacturing step. This can serve to clean the surface of contaminants; it can serve to remove particulates from the surface to prevent scratching; it can also modify the surface properties. In particular, the yield of integrated circuits after treatment by CMP can vary significantly. This can be due to particulates deposited onto the surface prior to CMP scratching the surface during CMP; it can be due to species remaining on the surface after CMP resulting in current leakage between neighbouring interconnects; it can be due to residues from the CMP process contaminating the surface and producing defects in the surface; it can also be due to corrosion of the surface during or between processing steps, producing further defects.

There are several current methods of treating a surface in the manufacture of an integrated circuit. The simplest method of treating a surface is to treat it with de-ionized water. This was one of the approaches in U.S. Pat. No. 6,444,569 (by Farkas et al.). This treatment removes from the surface large particulates and compounds which dissolve in water. However, this simple treatment does not remove all impurities from the surface of the substrate. In addition, the presence of water may also increase the rate of corrosion of the surface, thereby increasing the number of defects on the substrate surface.

U.S. Pat. No. 6,444,569 attempts to address the problems of the corrosion of substrates between processing steps through the addition of a corrosion inhibitor to a solution in which the substrate is placed in between manufacturing steps. US20040014319 (by Sahota et al.) uses a related strategy of adding a surfactant to a corrosion inhibitor solution used to treat a semiconductor substrate after CMP. Other solutions have also been applied to a substrate in between manufacturing steps. For example, U.S. Pat. No. 6,443,814 (by Miller et al.) and U.S. Pat. No. 6,464,568 (also by Miller et al.) disclose a cleaning solution comprising an organic chelating agent in the absence of oxidizers and abrasives.

However, these solutions for use in semiconductor processing do not adequately prevent corrosion of the substrate. In particular, the prior art solutions do not sufficiently address the problems relating to corrosion caused by water exposure of the wafers. For example, water exposure prior to Chemical Mechanical Polishing may lead to serious rip-out defects.

In addition, processes to dry a substrate after exposure to a rinse solution include exposure to light. This is a commonplace practice because it quickly dries the surface of the substrate. The processing also occurs in the presence of light so that the operators of the manufacturing equipment can observe what they are doing. It has been found that exposure to light may also induce corrosion. The present inventors have found that this is especially relevant after Chemical Mechanical Polishing, and the prior art solutions do not address this aspect of photo-induced corrosion.

### DESCRIPTION OF THE DRAWINGS

The present invention will now be described further, by way of example, with reference to the following drawings in which:

FIG. 1 depicts a typical prior art interconnect manufacturing process.

FIG. 2 depicts a typical interconnect manufacturing process, and the points at which the rinse formulation of the present invention may be applied.

FIG. 3 shows the results from Example 1 according to the present invention.

FIG. 4 shows the results from Example 2 according to the present invention.

FIG. 5 shows the results from Example 3 according to the present invention.

FIG. 6 shows the results from Example 4 according to the present invention.

FIG. 7 shows the results from Example 5 according to the present invention.

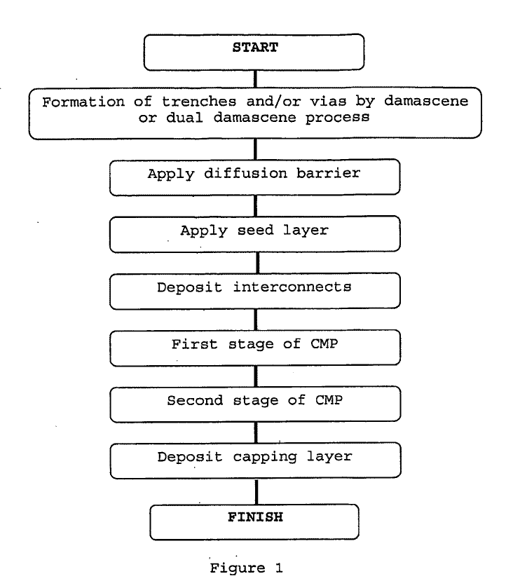

### DETAILED DESCRIPTION OF THE INVENTION

The present invention addresses some or all of the problems in the prior art. Accordingly, the present invention provides a liquid rinse formulation for use in semiconductor processing, characterised in that the liquid formulation contains:
i. a surface passivation agent; and
ii. an oxygen scavenger,
   wherein the pH of the rinse formulation is 8.0 or greater. The solution may, for example, be suitable for use in the manufacture of copper interconnects in a semiconductor device.

In contrast with the prior art, the present inventors have identified different types of corrosion inhibitors. The prior art has been mainly concerned with the use of corrosion inhibitors that form a passivation layer on the surface of the substrate. This passivation layer can be described as a thin film on the surface of the substrate which acts as a physical barrier to stop corrosive substances reaching the substrate. Materials suitable for use as a surface passivation agent are often aromatic compounds. They often have polarizable pi-systems, and this perhaps favours the interaction of the corrosion inhibitor with the surface. They often contain groups that are capable of hydrogen-bonding, perhaps enabling the self-assembly of the corrosion inhibitor on the surface.

The surface passivation agent in the rinse solution of the present invention may be a triazole, for example, one or more of 1,2,4-triazole, benzotriazole and/or tolytriazole. The present inventors have identified another class of corrosion inhibitor. This type of inhibitor acts as a chemical barrier to corrosion rather than a physical barrier to corrosion. In particular, the present inventors have found that corrosion of a metal layer in a liquid environment is caused by the exposure of the surface to oxidizing species. This corrosion leads to the formation of defects on the surface. The oxidizing species may originate from dissolved oxygen in the liquid, or from oxygen contained in micro-bubbles or nano-bubbles at the surface of the substrate, or from oxygen physisorbed onto the surface of the substrate. These oxidizing species may therefore include O₂, O₃ and H₂O₂. The oxidizing species may also originate from, for example, impurities picked up from the platen during CMP, or impurities remaining on the surface after exposure to the bath used for electroless deposition. The oxidizing species may therefore also include, for example, ammonium persulphate.

The present inventors have found that this oxidation of the surface not only results in corrosion of the surface, but also affects the efficiency of a surface passivation agent acting at the surface. The uncontrolled oxidation of the surface metal layer has been found to adversely affect the uniformity of the surface passivation films and to lead to the increased formation of defects on the surface of the substrate.

Accordingly, the present invention includes an oxygen scavenger in its rinse formulation. The role of the oxygen scavenger is to reduce the concentration of oxidizing species to which the surface is exposed. It fulfils this role by being particularly susceptible to oxidation, and reacting with any oxidizing species in solution. These oxidizing species may, for example, be reactive oxygen species.

As described above, the presence of an oxygen scavenger may be particularly important in the presence of a surface passivation agent. An oxygen scavenger is reactive towards oxidizing species because it is more readily oxidized by an oxidizing species than the surface metal layer. The oxygen scavenger may therefore be considered as a reducing species. The oxygen scavenger may, for example, contain a weak double bond that is susceptible to oxidation, such as hydrazine. It may be an inorganic molecule capable of reducing oxidizing species, such as a salt where the anion comprises one or more of a sulfite, bisulfite and nitrite, and where the cation comprises one or more of sodium, potassium or ammonium. It may also be an organic molecule with a low reduction potential, capable of acting as a reducing agent, such as hydroquinone, or, to take another example, it may be ascorbic acid.

The oxygen scavenger of the present invention preferably comprises one or more of gallic acid, hydroquinone, pyrogallol, cyclohexanedione, a sulfite, tocopherol, hydrazine, a bisulfite, and/or a nitrite. It may also be ascorbic acid, used in combination with any of the other listed anodic inhibitors, or by itself. The selection of these particular anodic inhibitors is also advantageous because their reaction products with oxidizing species do not form insoluble precipitates on the surface of the substrate.

The oxygen scavenger may be a species that is capable of reacting with molecular oxygen, or with reactive oxygen species originating from molecular oxygen, for example O₃ or the hydroxyl radical. Oxygen scavengers of this type (which are capable of reacting with oxygen-containing species) are particularly important when the substrate is processed while exposed to light. As described above, this may be due to the processing steps being carried out in the presence of light to enable an operator to observe what they are doing; in addition, it is sometimes beneficial to dry a substrate after a processing step by exposure to light because this causes a quick evaporation of the solvent. The rate of formation of reactive oxygen species is usually considered to be enhanced in the presence of light, and therefore the role of an oxygen scavenger of this type is even more important under these conditions.

Further examples of surface passivation agents, oxygen scavengers will, of course, be evident to the person skilled in the art.

The present inventors have found that the combination of 1,2,4-triazole and an oxygen scavenger, especially ascorbic acid, has been found to be particularly effective at both cleaning the surface and reducing corrosion of copper. In particular, the present inventors have found that the combination of 1,2,4-triazole and an oxygen scavenger may be even more effective compared with some other triazole-based solutions.

The present inventors have found that the surface passivation agent and the oxygen scavenger may be present in the rinse formulation in a ratio of their weight percentages between 10:1 to 1:10. One reason for the lower limit is that, in order for the oxygen scavenger to enhance the efficiency of the surface passivation agent, a certain minimum proportion of oxygen scavenger should preferably be present in solution to prevent the uncontrolled oxidation of the surface. The minimum of the ratio of surface passivation agent to oxygen scavenger may be about 0.1, (i.e. 1:10 or 1:<10). This is again because, in order for the surface passivation agent to act efficiently, there must be a certain minimum proportion of surface passivation agent at the surface. The ratio may be 1:5 to 5:1, such as 1:2 to 2:1, and the ratio may even be about 1 (i.e. 1:1).

The concentration of the total amount of corrosion inhibitor may be from 0.1 to 5 wt %, or, in other words, 0.1 to 5 g of corrosion inhibitor may be contained in every 100 g of the solution. The concentration of corrosion inhibitor may also be 2 to 5 wt %. The concentration of the total amount of oxygen scavenger may be from 0.1 to 5 wt %, for example from 2 to 5 wt %. Reasons for these preferred amounts of oxygen scavenger and surface passivation agent are similar to those for the preferred ratios of these two components.

It will be understood that these concentrations, and all concentrations described herein are concentrations that substrate may be exposed to during rinsing. It is, for example, possible to make a concentrated form of the rinse solution and to dilute either just before or actually during its application to the substrate.

The rinse formulation may comprise a number of solvents. These are chosen to dissolve and/or suspend the components of the rinse formulation, to wet the surface of the substrate, and to dissolve and/or suspend impurities on the surface of the substrate. The solvent may comprise one or more of water, ethanol, and/or isopropanol. For example, the rinse formulation may comprise water. It will be understood that some of the components may not be soluble in pure water, so that often a mixture of water and another, solvent will be used. If this second solvent is more volatile than water, such as in the case of ethanol or isopropanol, this has the additional advantage that the rate of drying at the surface is quicker than compared to water as a solvent by itself. This may be considered an advantage, taking into account that the present inventors have found corrosion may result from drying through exposure to light.

Although the rinse formulation may simply contain a surface passivation agent, an oxygen scavenger (or, in other words, an anti-oxidant) and a solvent at pH 8.0 or above, the rinse formulation may also contain a number of other components. The formulation preferably further comprises one or more of a surfactant, a complexing agent, and/or a pH-modifying agent.

A surfactant may be added to the rinse formulation to act in a number of roles. It may help to wet the surface of the substrate; it may help to solubilize impurities on the surface of the substrate; it may help solubilize other components in the rinse formulation; it may also solubilize impurities on the surface of the substrate.

The surfactant may comprise a poly-alkylene glycol, for example one or more of poly-ethylene glycol, a poly-alkylene block co-polymer such as a ethylene glycol-propylene glycol block co-polymer, acetal-oxymethylene block copolymer (POM), and/or polypropyleneglycol. The present inventors have recognised that, unlike some other types of surfactant, these surfactants do not form micelle and related structures. Therefore they are not sensitive to precipitation, which, if it did occur, may result in the deposition of precipitates on the surface and the potential of damage and the creation of defects in additional processing steps. In addition, these surfactants may not diminish the function of either the surface passivation agent or the oxygen scavenger, unlike some other surfactants.

The surfactant may comprise either a Tetronic surfactant, or a Pluronic surfactant (these are polyethylene glycol-polypropylene glycol block co-polymers manufactured by, for example BASF). The present inventors have recognised that these surfactants can wet both hydrophobic and hydrophilic surfaces homogenously. In addition, the surface-wetting properties can be adjusted depending on the precise application by varying the size and relative amounts of the ‘blocks’ in the block copolymer. The co-polymers are also generally hydroxyl terminated. They may have a molecular weight of from 1000 to 25000 g/mol, such as from 2000 to 3500 g/mol, and may contain from 20 to 60 weight % ethylene oxide units.

The surfactant may also be anionic and may comprise one or more of a carboxylate, a sulfate, a sulfonate, and a phosphate. It may also, be cationic and, for example, comprise an alkyl ammonium species. It may be amphoteric and comprise, for example, both ammonium and carboxylate species. Finally, it may be neutral and be an ethoxylate species or be a fluorocarbon or silicone surfactant.

Whatever the surfactant, the total concentration of surfactant may be 0.0001 to 0.4 wt %, or, in other words, 0.0001 to 0.4 g of surfactant may be contained in every 100 g of the solution. For example, 0.005 to 0.4 wt % surfactant may be contained in the solution.

A complexing agent may be added to the rinse formulation. The complexing agent may help to solubilize any precipitates on the surface, for example residues remaining from the CMP slurry after CMP. The complexing agent may also be used to reduce the concentration of, for example, sodium ions at the surface, which can cause current to leak between neighbouring interconnects when in use in the integrated circuit. The complexing agent may comprise one or both of EDTA (ethylenediamine tetraacetic acid) and EDDHA (ethylenediamine di(o-hydroxyphenylacetic) acid), and their salts. The complexing agent may be at a concentration of 0.0001 to 0.5 wt %, such as 0.001 to 0.01 wt %.

The rinse solution may not contain abrasives. Abrasives are usually found in the slurry used for CMP. The present inventors have found that contaminants from the platen in CMP may cause corrosion, and in particular abrasives, such as silica abrasives, corrode and scratch the surface of a substrate. Therefore the rinse solution, at any stage of the processing of the substrate, preferably does not contain abrasives.

The rinse solution has a pH of 8.0 or greater, for example 8.5 or 9.0 or greater. The pH of the rinse solution is measured at room temperature (at 25° C.). The present inventors have found that the corrosion of the surface may be reduced at a pH of 8.0 or greater. One reason for this is that the corrosion process involves the reaction of copper metal at the surface of an interconnect, producing copper ions. These ions are less soluble in basic conditions than acidic or neutral conditions. Since the dissolving of the ions is a significant thermodynamic factor in corrosion, keeping the substrate in basic conditions may reduce the rate of corrosion.

Furthermore, the effectiveness of certain surface passivation agents is increased at basic pH. For example, a triazole compound may become protonated in acidic conditions, and this will affect the interaction of the triazole with the surface. This may be because, for example, the triazole may be better solvated in its protonated form, or it may be attracted or repelled by a charged surface, or by an electrical double layer at a charged surface. Other factors may also contribute to the interaction of the surface passivation agent with the surface.

The effect of pH on the effectiveness of a surface passivation agent is illustrated in Examples 4 and 5 for a triazole. In this case, a basic pH is seen to facilitate the function of the surface passivation agent.

The effect of pH on the oxygen scavenger may also be considered. For example, ascorbic acid may become deprotonated in basic conditions, and this may affect its ability to act as an oxygen scavenger. In the case of ascorbic acid, the present inventors have recognised that ascorbic acid is thought to act in its role as an oxygen scavenger in its deprotonated form. The pH of the rinse formulation may therefore be at least the pKₐ of ascorbic acid (4.1). Therefore by using a rinse formulation with pH 8, nearly all the ascorbic acid will be deprotonated and able to act in its role as an oxygen scavenger.

The rinse formulation may comprise an organic acid in its deprotonated form, which may act as a buffer to maintain a constant pH during treatment of the substrate with the rinse formulation. It may, for example, comprise one or both of a citrate and an ascorbate (e.g. sodium citrate or sodium ascorbate, and/or potassium salts thereof). In this case, the ascorbate may be added to the rinse formulation because of its buffering properties, as well as its properties as an oxygen scavenger.

The rinse formulation may also comprise (in combination with the citrate and/or ascorbate or by themselves) salts of one or more of oxalic, glycolic, malic, succinic and gallic acids (such as the potassium or sodium salts). A base may also be added to the rinse formulation, for example one or both of tetramethyl ammonium hydroxide and/or ammonia.

The rate of corrosion by oxygen may also preferably be reduced by using deoxygenated solvents. It will be understood that reducing the amount of oxygen in solution results in a reduced amount of oxygen at the surface of the substrate, and therefore a reduced rate of oxidation. Techniques of deoxygenation include bubbling a gas such as nitrogen or carbon dioxide (i.e. a gas not containing oxygen) through the solvent; they include placing the solvent under vacuum and then releasing the vacuum with a non-oxygen gas; and they include the freeze-pump-thaw method.

The rinse solution may therefore be free or substantially free of oxygen. Preferably, the concentration of oxygen dissolved in the formulation is less than 10% of the saturated oxygen concentration, more preferably less than 5% of the saturated oxygen concentration. In this instance, the rate of corrosion at the surface may be significantly reduced, especially in the presence of light.

The temperature of the formulation may be in the range of 5 to 85° C. If the rinse formulation is too cold then it will not dissolve contaminants at the surface of the substrate; however, if it is too hot, then the rate of corrosion will be increased. The present inventors have found an ideal balance of these factors with the temperature of the formulation may be in the range of 10 to 50° C.

The rinse formulation may be used either in a dynamic manner—i.e. it may be applied onto the substrate and allowed to drip off the substrate—or it may be used in a static manner—i.e. the substrate is submerged in the formulation for a given period of time. In the case of static treatment, the rinse formulation may be used as a ‘holding solution’ in which the substrate is submerged or placed between processing steps to prevent corrosion.

The present invention also provides the use of a rinse formulation as described above in the manufacture of an integrated circuit from a substrate. It may, for example, be applied to the substrate prior to, during, and/or after Chemical Mechanical Polishing.

The present invention also provides a process for treating the surface of a substrate for use in semiconductor processing, the process comprising a step (A) of contacting the surface of the substrate with the rinse formulation as described above. Preferably, the process further comprises a step (B) of subjecting the surface to Chemical Mechanical Polishing, which may be carried out before, after or at the same time as step A. Preferably, the process also comprises a step (C) of rinsing the surface with deionised water, carried out either directly before step A or directly after step A, or both directly before and directly after step A.

It will be understood that the application of the rinse formulation before or after Chemical Mechanical Polishing may occur either with the substrate removed from the CMP apparatus, or with the substrate actually in place in the CMP apparatus. In this latter case, a down-force may be applied to the substrate for some of or all of the rinsing process. Usually, the magnitude of this down-force will be less or equal than that applied during CMP.

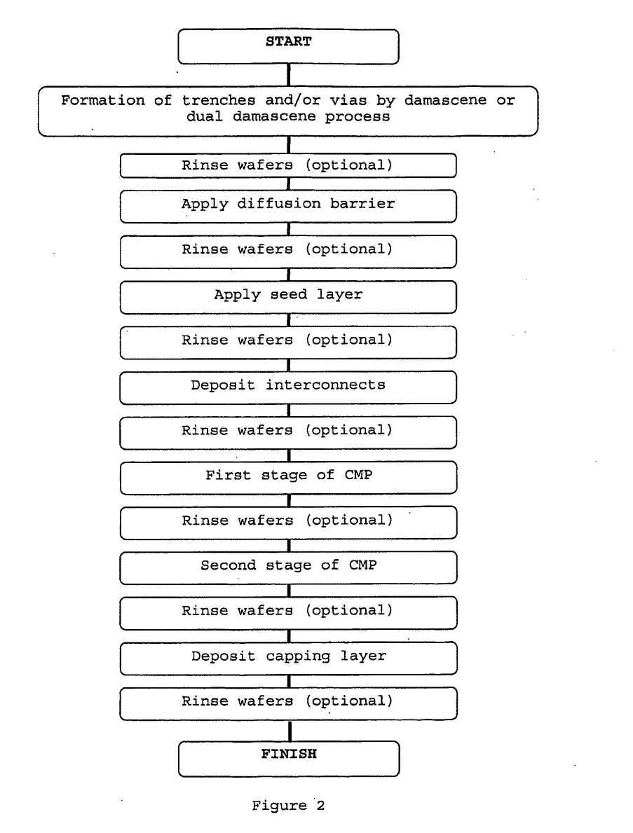

As shown in FIG. 2, the rinse formulation may be applied at any stage of the manufacture of an interconnect (in the ‘rinse wafers’ stage(s)). It may be applied after the formation of the trenches and/or vias on the surface of the substrate. It may be applied after the application of the diffusion barrier on the surface. It should be noted that at present physical vapour deposition is usually used for the deposition of the barrier layer, and normally no rinse step is carried out afterwards. However, the rinse formulation of the present invention may also be used in conjunction with liquid phase methods of depositing a barrier layer know in the prior art.

The rinse formulation may also be applied after the application of the seed layer to the trenches and/or vias. It may be applied after the deposition of the interconnect material into the trenches and/or vias It may be applied after the first polishing step of CMP. It may be applied after the second polishing step of CMP. Finally, it may be applied after the deposition of a capping layer on top of the interconnects. FIG. 2 only illustrates an example of a manufacturing process for the formation of an interconnect, and it can be altered as would be appreciated by the skilled person in the art. For example, in some instances, one or several of the steps will not be carried out, or extra steps will be added in between each step as the particular technology requires.

The process preferably also comprises removing the rinse formulation from the surface following step (A). This may preferably be carried out in the presence of a light source.

Finally, the present invention provides the use of an oxygen scavenger in a rinse formulation for use in semiconductor processing in the prevention of corrosion. The present invention also provides the use of a rinse formulation as defined above in the prevention of corrosion of a metal surface in the manufacture of a semiconductor device.

### EXAMPLES

In these examples, the staple rinse formulation is labelled as solution A. This aqueous solution contains:
0.3 wt % polyethylene glycol, and
3 wt % 1,2,4-triazole.

The pH of the solution has been adjusted to 8.5 by the addition of ammonia (i.e. each 100 g of the solution contains 0.3 g of polyethylene glycol and 3 g of 1,2,4-triazole, the remainder being water and ammonia solution).

Polished patterned wafers were immersed for 1 hour in the respective cleaning solutions under ambient fluorescent lights. These samples were then dried and optical micrographs were taken on the samples treated with different solutions.

All experiments were carried out at room temperature (20° C.) and under normal ambient laboratory conditions.

### Example 1

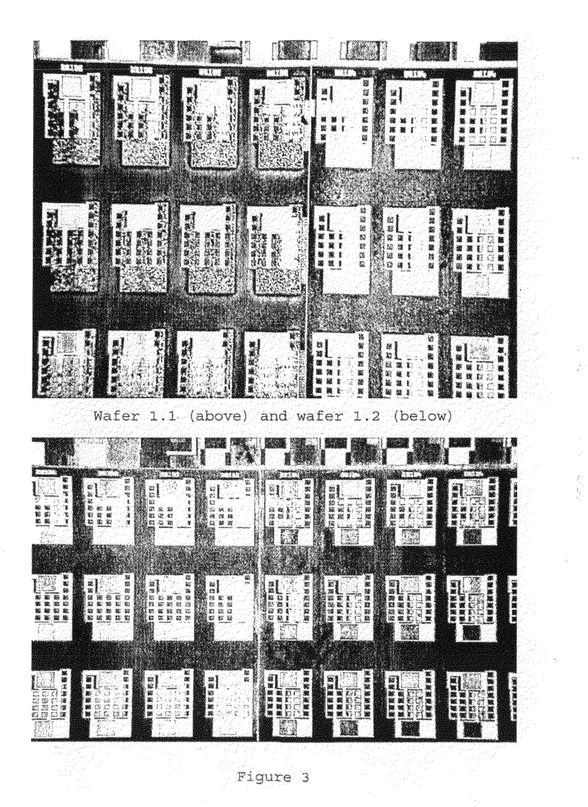

Patterned substrates, 1.1 and 1.2, were polished by CMP. The two substrates were removed from the CMP apparatus without any further processing. The substrates were photographed and then placed in two different rinse formulations, one for each substrate. The first formulation, in which wafer 1.1 was placed, was solution A; the second solution, in which wafer 1.2 was placed, was the solution A with an additional 3 wt % ascorbic acid added (i.e. 3 g of ascorbic acid was added to 97 g of solution A) the pH of the solution B has been adjusted to 8.5 with ammonia. The wafers submerged in the solutions were then left exposed to ambient laboratory fluorescent light for 1 hour. The wafers were then removed form the solutions, rinsed with water, dried with nitrogen and photographed once again. Photographs of the two wafers are shown in FIG. 3 (wafer 1.1 in FIG. 3.1 and wafer 1.2 in FIG. 3.2. The substrates are shown on the right before being placed in the rinse formulations and are shown on the left after being placed in the rinse formulations and exposed to light).

It is clear from FIG. 3 that wafer 1.1 has undergone significant corrosion in the hour that it was left submerged in formulation solution A. The growth of dendrites is apparent on the copper surface from the uneven appearance of the wafer. These dendrites act to increase the conductivity, and hence the electronic communication, between neighbouring interconnects. However, wafer 1.2 shows very little sign of corrosion having been treated under the same conditions, the only difference being that ascorbic acid was added to the formulation in which the wafer was placed. It can therefore be concluded that the addition of ascorbic acid to the rinse solution prevents the corrosion of the copper wafers.

### Example 2

300 mm annealed copper wafers were rinsed with the following formulation:
2.1 Solution A
2.2 Solution A, diluted by 20 times, (i.e. 19 (volume) parts of water are added to every 1 part of solution A)—control solution
2.3 Solution A with 3 wt % of ascorbic acid added, then diluted by 20 times (i.e. 3 g of ascorbic acid was added to 97 g of solution A, and then 1 part of the resulting solution was added to 19 parts water).
2.4 Solution A with 4 wt % of ascorbic acid added, then diluted by 20 times
2.5 Solution A with 5 wt % of ascorbic acid added, then diluted by 20 times

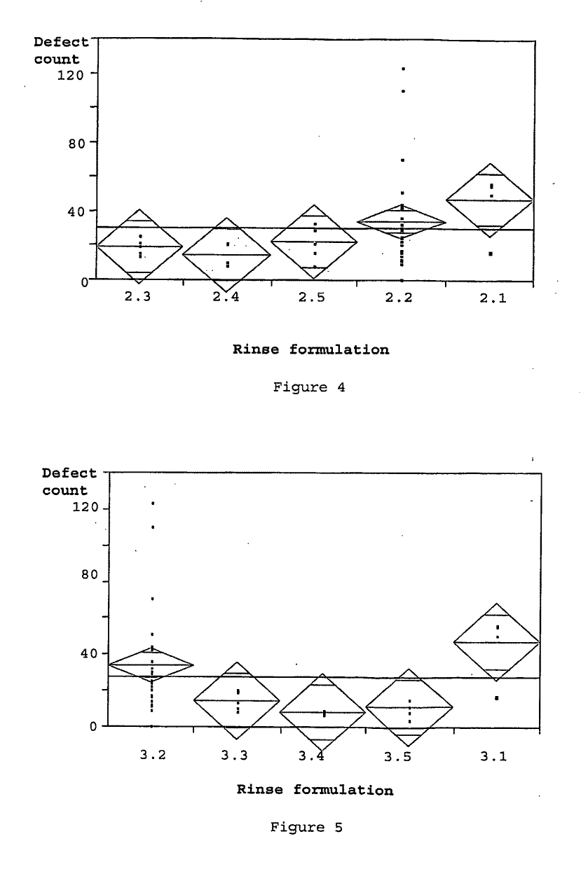

The surface of each wafer was then polished by CMP and the number of defects larger than 1 μm after polishing were measured on a KLA Tencor SP1. Five wafers were exposed to each formulation, except for the control formulation 2.2 with which 30 wafers were tested. FIG. 4 shows the results. It shows the number of defects measured which were greater than 1 μm in diameter (on the y-axis) for the wafers subject to treatment by each formulation (listed on the x-axis). The mean number of defects is illustrated for each formulation by the line dissecting the middle of the diamond superimposed on top of each set of results, and the lines at the top and bottom of the diamond represents the mean plus and minus three times the standard deviation for each set of results.

From FIG. 4, it can be seen that treatment with the formulations containing ascorbic acid (formulations 2.3, 2.4 and 2.5) leads to lower average defect density than the formulations not containing ascorbic acid (formulations 2.1 and 2.2). The best result was obtained for a formulation containing 3 wt % corrosion inhibitor and 4 wt % oxygen scavenger—i.e. at a ratio of these components of 3:4 (i.e. about 1:1).

### Example 3

300 mm annealed copper wafers were polished by CMP. Pressure was decreased from the substrate from 2.2 psi to 1 psi, and the platen was maintained at a rate of revolution of (110 rpm). The rinse formulations detailed below were then applied to the platen at a higher flow rate of the supply of slurry during CMP (550 ml/min vs. 250 ml/min) for 15 seconds. Five wafers were exposed to each formulation, except for the control formulation 3.2 with which 30 wafers were tested:
3.1 Solution A—these are ‘control’ results collected on the same day as examples 3.3 to 3.5
3.2 Solution A—these are ‘control’ results collected over 1 month of use of the CMP apparatus
3.3 Solution A with 3 wt % of ascorbic acid added
3.4 Solution A with 4 wt % of ascorbic acid added
3.5 Solution A with 5 wt % of ascorbic acid added

The wafers were dismounted from the CMP apparatus, and then the numbers of defect larger than 1 μm after polish were measured on a KLA Tencor SP1. The results are shown in FIG. 5. It shows the number of defects recorded (on the y-axis) for the wafers subject to treatment by each formulation (listed on the x-axis). As in FIG. 4, the mean number of defects is illustrated for each formulation by the line dissecting the diamond superimposed on top of each set of results, and the mean top and bottom of the diamond represents the mean plus three times the standard deviation for each set of results.

From FIG. 5, it can be seen that treatment with the formulations containing ascorbic acid (formulations 3.3, 3.4 and 3.5) leads to lower average defect density than the formulations not containing ascorbic acid (formulations 3.1 and 3.2). As was the case in Example 2, the best result was obtained for a formulation containing 3 wt % corrosion inhibitor and 4 wt % oxygen scavenger—at a ratio of these components of 3:4 (i.e. at a ratio of about 1:1).

### Example 4

Two solutions were prepared:
4.1 solution A with 3 wt % ascorbic acid added adjusted to pH 8.5
4.2 solution A with 3 wt % ascorbic acid added, adjusted to pH 3.6

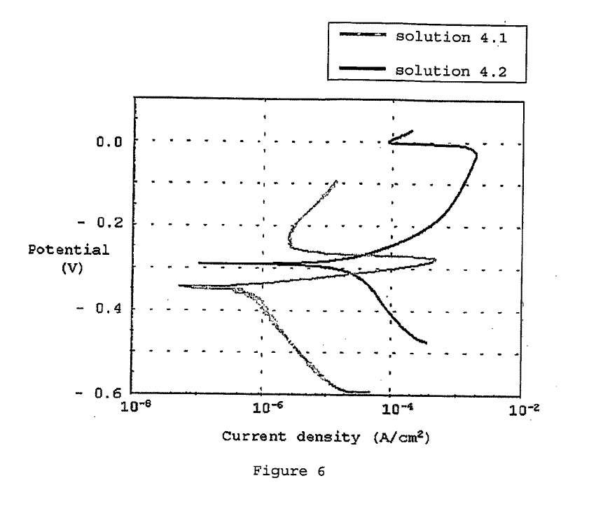

Tafel plots of electrodes plated with 1 micrometer of copper placed in the two solutions were then recorded. The results are shown in FIG. 6, solution 4.1 shown in grey and solution 4.2 shown in black.

In FIG. 6 for solution 4.2, the reduction of H⁺ ions or H₂O itself accounts for the significant current densities at negative potentials (i.e. at more negative than −0.29 V). At potentials more positive than −0.29 V for solution 4.2, the following reaction accounts for the increase in current density:

Cu₍ₛ₎→+Cu²⁺_{(aq)}+2e⁻

At potentials close to 0 for solution 4.2, the current density is observed to drop. This is thought to be because nearly all the copper at the anode has dissolved into solution.

For solution 4.1, the reduction of H⁺ ions or H₂O accounts for the significant current densities at potentials more negative than −0.345 V. However, at potentials less negative than −0.345 V, the current density is observed to increase slightly and then to decrease. This behaviour is attributed to the formation of a surface passivation layer of the triazole on the surface of the copper electrode, which prevents the oxidation of the copper surface. This should be contrasted with solution 4.2, in which oxidation of the copper surface is observed in the presence of the triazole.

Accordingly, it is observed that a triazole surface passivation agent is more effective at preventing oxidation in alkali conditions, for example at a pH of greater than 8.0.

### Example 5

Three solutions were prepared:
5.1 Solution A (at pH 8.5)
5.2 Solution A with 3 wt % ascorbic acid added adjusted to pH 3.6
5.3 Solution A with 3 wt % ascorbic acid added adjusted to pH 8.5

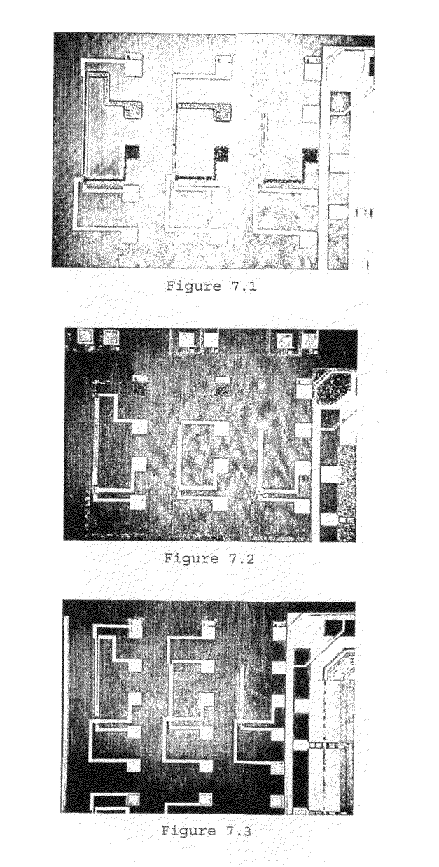

Three patterned substrates, which had been polished by CMP, were then separately treated with the three solutions while being exposed to light according to the method described in Example 1. A photograph of the substrate after treatment with solution 5.1 is shown in FIG. 7.1; the substrate treated in solution 5.2 is shown in FIG. 7.2; and the substrate treated in solution 5.3 is shown in FIG. 7.3.

It is seen in FIG. 7 that solution 5.3, which is an example of the present invention, is better at preventing corrosion than either solutions 5.1 and 5.2. Therefore the presence of the oxygen scavenger and the basic conditions combine to result in the superior performance of rinse formulation 5.3.

1. A liquid rinse formulation for use in semiconductor processing, the liquid formulation comprises:
i. 1,2,4-triazole,
ii. an oxygen scavenger, and
iii. a surfactant comprising one or more of poly-ethylene glycol, an ethylene glycol-propylene glycol block co-polymer, an acetal-oxymethylene block copolymer (POM), and/or poly-propylene glycol;
wherein the pH of the rinse formulation is 8.0 or greater.

2. A rinse formulation according to claim 1, wherein the oxygen scavenger comprises one or more of ascorbic acid, gallic acid, hydroquinone, pyrogallol, cyclohexanedione, a sulfite, tocopherol, hydrazine, a bisulfite, and/or a nitrite.

3. A rinse formulation according to claim 1, wherein the pH of the formulation is 8.5 or greater.

4. A rinse formulation according to claim 2, wherein the oxygen scavenger comprises ascorbic acid.

5. A rinse formulation according to claim 4, wherein the ratio of the weight percentage of ascorbic acid to 1,2,4-triazole in the formulation is 1:10 to 10:1.

6. A rinse formulation according to claim 1, wherein the liquid comprises one or more of water, ethanol, and/or isopropanol.

7. A rinse formulation according to claim 1, wherein the formulation comprises a complexing agent, and/or a pH-modifying agent.

8. A rinse formulation according to claim 7, wherein the complexing agent comprises one or more of EDTA and EDDHA, and their salts.

9. A rinse formulation according to claim 1, wherein the rinse formulation is free or substantially free from oxygen.

10. A process for treating the surface of a substrate for use in semiconductor processing, the process comprising:
a step (A) of contacting the surface of the substrate with a rinse formulation as comprises:
i. 1,2,4-triazole,
ii. an oxygen scavenger, and
iii. a surfactant comprising one or more of poly-ethylene glycol, an ethylene glycol-propylene glycol block co-polymer, an acetal-oxymethylene block copolymer (POM), and/or poly-propylene glycol;
wherein the pH of the rinse formulation is 8.0 or greater.

11. The process according to claim 10, wherein the process further comprises:
a step (B) of subjecting the surface to Chemical Mechanical Polishing,
wherein step A may be carried out before, during and/or after step B.

12. The process according to claim 10, wherein the process further comprises:
a step (C) of rinsing the surface with deionised water,
wherein step C may be carried out either directly before step A or directly after step A, or both directly before and directly after step A.

13. The process according to claim 10, wherein the rinse formulation is substantially free of oxygen when it is contacted with the surface of the substrate.

14. (canceled)

15. A rinse formulation according to claim 2, wherein the pH of the formulation is 8.5 or greater.

16. A rinse formulation according to claim 2, wherein the liquid comprises one or more of water, ethanol, and/or isopropanol.

17. A rinse formulation according to claim 3, wherein the liquid comprises one or more of water, ethanol, and/or isopropanol.

18. A rinse formulation according to claim 3, wherein the formulation comprises a complexing agent, and/or a pH-modifying agent.

19. A rinse formulation according to claim 4, wherein the formulation comprises a complexing agent, and/or a pH-modifying agent.

20. The process according to claim 11, wherein the process further comprises:
a step (C) of rinsing the surface with deionised water,
wherein step C may be carried out either directly before step A or directly after step A, or both directly before and directly after step A.

21. The process according to claim 11, wherein the rinse formulation is substantially free of oxygen when it is contacted with the surface of the substrate.
